(19) United States
(12) Patent Application Publication
(10) Pub. No.: US 2025/0331392 A1
(43) Pub. Date: Oct. 23, 2025

(54) DISPLAY PANEL AND DISPLAY DEVICE

(71) Applicant: HKC CORPORATION LIMITED, Shenzhen (CN)

(72) Inventors: Chenchen JIANG, Shenzhen (CN); Haijiang YUAN, Shenzhen (CN)

(21) Appl. No.: 19/177,698

(22) Filed: Apr. 14, 2025

(30) Foreign Application Priority Data
Apr. 17, 2024 (CN) 202410465554.2

(51) Int. Cl. H10K 59/80; H10K 102/00; H10K 102/10

(52) U.S. Cl. CPC H10K 59/80517; H10K 59/80518; H10K 2102/103; H10K 2102/351

(57) ABSTRACT

A display panel and a display device are disclosed. The display panel includes a substrate, a pixel defining layer, and a light-emitting element layer. Each light-emitting element includes a bottom electrode, a light-emitting layer, and a top electrode, and includes a middle region and a peripheral region arranged around the middle region. The bottom electrode includes a reflective electrode layer, and a transparent electrode layer arranged on the side of the reflective electrode layer facing away from the substrate. The transparent electrode layer includes a first conductive layer arranged corresponding to the middle region and a second conductive layer arranged corresponding to the peripheral region, the first and second conductive layers being electrically connected. The thickness of the first conductive layer is less than that of the second conductive layer. At each light-emitting element, the brightness of the peripheral region is higher than that of the middle region.

### CROSS-REFERENCE TO RELATED APPLICATIONS

This application claims the priority and benefit of Chinese patent application number 2024104655542, titled “Display Panel and Display Device” and filed Apr. 17, 2024 with China National Intellectual Property Administration, the entire contents of which are incorporated herein by reference.

### TECHNICAL FIELD

This application relates to the field of display technology, and more particularly relates to a display panel and a display device.

### BACKGROUND

The description provided in this section is intended for the mere purpose of providing background information related to the present application but does not necessarily constitute prior art.

An Organic Light Emitting Diode (OLED) display panel features self-luminescence, high contrast, wide viewing angle, and high response speed. Its working principle is as follows. An ITO transparent electrode and a metal electrode are used as the anode and cathode of the device. Under the drive of a certain voltage, electrons and holes are injected from the cathode and anode into the electron transport layer and the hole transport layer respectively. The electrons and holes migrate to the light-emitting layer through the electron transport layer and the hole transport layer respectively, and meet in the light-emitting layer to form excitons which excite the electrons in the light-emitting layer to radiate visible light.

However, due to manufacturing process reasons, the light-emitting elements in the OLED display panel may be prone to the problem of a bright center and dark edges. In view of this, the technicians in this field are in urgent need of a solution.

### SUMMARY

It is therefore one purpose of the present application to provide a display panel and a display device, which increases the thickness of the transparent electrode layer in the peripheral region of the bottom electrode to improve the brightness of the peripheral region of the display panel and make the light emitted by the light-emitting elements more uniform, thus enhancing the display effect of the display panel.

The present application discloses a display panel, including an opening area and a non-opening area. The display panel includes a substrate, a pixel defining layer, and a light-emitting element layer. The pixel defining layer is arranged on the substrate and located in the non-opening area. The light-emitting element layer is arranged on the substrate and located in the opening area. The light-emitting element layer includes a plurality of light-emitting elements, which are arranged in an array. Each of the light-emitting elements includes a bottom electrode, a light-emitting layer, and a top electrode. Each light-emitting element includes a middle region and a peripheral region, where the peripheral region is arranged around the middle region. The bottom electrode includes a transparent electrode layer and a reflective electrode layer. The transparent electrode layer is arranged on the side of the reflective electrode layer facing away from the substrate. The transparent electrode layer includes a first conductive layer and a second conductive layer that are electrically connected. The first conductive layer is arranged corresponding to the middle region, and the second conductive layer is arranged corresponding to the peripheral region. The thickness of the first conductive layer is less than the thickness of the second conductive layer. Of each same light-emitting element, the brightness of the peripheral region is higher than the brightness of the middle region.

In some embodiments, the refractive index of the second conductive layer is greater than the refractive index of the first conductive layer.

In some embodiments, the refractive index of the second conductive layer lies in the range between 2 and 2.3, and the refractive index of the first conductive layer lies in the range between 1.6 and 1.8.

In some embodiments, the second conductive layer is formed of an indium tin oxide material, and the first conductive layer is formed of an indium zinc oxide material.

In some embodiments, the bottom electrode further includes an isolation layer, which is arranged in the peripheral region. The isolation layer is arranged between the transparent electrode layer and the reflective electrode layer.

In some embodiments, the thickness of the second conductive layer lies in the range of 5 nm to 20 nm, and the thickness of the first conductive layer lies in the range of 4 nm to 10 nm. The difference between the thickness of the second conductive layer and the thickness of the first conductive layer lies in the range between 0.5 nm and 10 nm.

In some embodiments, the peripheral region includes a first peripheral region, a second peripheral region, and a third peripheral region. The first peripheral region is arranged around the middle region. The second peripheral region is arranged around the first peripheral region. The third peripheral region is arranged around the second peripheral region. The second conductive layer includes a first edge conductive layer, a second edge conductive layer, and a third edge conductive layer. The first edge conductive layer is arranged corresponding to the first peripheral region. The second edge conductive layer is arranged corresponding to the second peripheral region. The third edge conductive layer is arranged corresponding to the third peripheral region. The thicknesses of the first edge conductive layer, the second edge conductive layer, and the third edge conductive layer gradually increase.

In some embodiments, the display panel further includes an encapsulation layer and a color filter layer. The encapsulation layer is configured to encapsulate the light-emitting element layer. The encapsulation layer is arranged on the light-emitting element layer. The color filter layer is arranged on the encapsulation layer. The color filter layer includes a red filter, a green filter, a blue filter, and a black matrix. The black matrix is arranged in the non-opening area, and a plurality of openings are defined in the black matrix corresponding to the opening area. A plurality of red filters, green filters, and blue filters are arranged in the openings respectively. The area of the blue filter is greater than or equal to the area of the green filter. The area of the green filter is greater than or equal to the area of the red filter.

In some embodiments, the light-emitting elements include a red light-emitting element, a green light-emitting element, and a blue light-emitting element. The light-emitting area of the red light-emitting element is less than or equal to the light-emitting area of the green light-emitting element. The light-emitting area of the green light-emitting element is less than or equal to the light-emitting area of the blue light-emitting element. The first conductive layer is disposed in at least the red light-emitting element.

The present application further discloses a display device, including a driving circuit and the above-mentioned display panel, where the driving circuit is configured to drive the display panel to display.

In this application, the brightness of the peripheral region is increased by dividing the light-emitting area of each light-emitting element into a middle region and a peripheral region and increasing the thickness of the transparent electrode layer in the bottom electrode of the peripheral region. The light emission of the peripheral region of the light-emitting element is enhanced, and when displaying, the light emitted by the light-emitting element is made more uniform, thereby improving the display effect of the display panel. Furthermore, the edge of the light-emitting element suffers from severe light attenuation, especially when the display panel is viewed at a certain angle, which causes the problem of color deviation at a large viewing angle. The present application increases the thickness of the transparent electrode layer in the peripheral region, so that the chromaticity value of the peripheral region of the light-emitting element is better than the chromaticity value of the middle region. For example, the chromaticity value of the peripheral region of the blue light-emitting element may be 0.045˜0.048, and the chromaticity value of the middle region domain can be 0.048˜0.052, which improves the color deviation phenomenon under a large viewing angle and improves the display effect.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel according to the present application.

FIG. 2 is a schematic diagram of a light-emitting element according to the present application.

FIG. 3 is a schematic diagram of a thickness change of a transparent electrode layer and a current efficiency of a light-emitting element according to the present application.

FIG. 4 is a schematic diagram of a first bottom electrode according to the present application.

FIG. 5 is a schematic diagram of a color filter layer according to the present application.

FIG. 6 is a schematic diagram of a second bottom electrode according to the present application.

FIG. 7 is a schematic diagram of a third bottom electrode according to the present application.

FIG. 8 is a schematic diagram of a display device according to the present application.

In the drawings: 100, display panel; 101, opening area; 102, non-opening area; 110, substrate; 120, light-emitting element; 121, bottom electrode; 122, light-emitting layer; 123, top electrode; 130, middle region; 131, peripheral region; 132, first peripheral region; 133, second peripheral region; 134, third peripheral region; 140, transparent electrode layer; 141, reflective electrode layer; 142, first conductive layer; 143, second conductive layer; 144, third electrode layer; 145, fourth electrode layer; 146, isolation layer; 147, first edge conductive layer; 148, second edge conductive layer; 149, third edge conductive layer; 150, pixel defining layer; 160, encapsulation layer; 170, color filter layer; 171, color filter; 172, black matrix; 180, lower transparent electrode layer; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

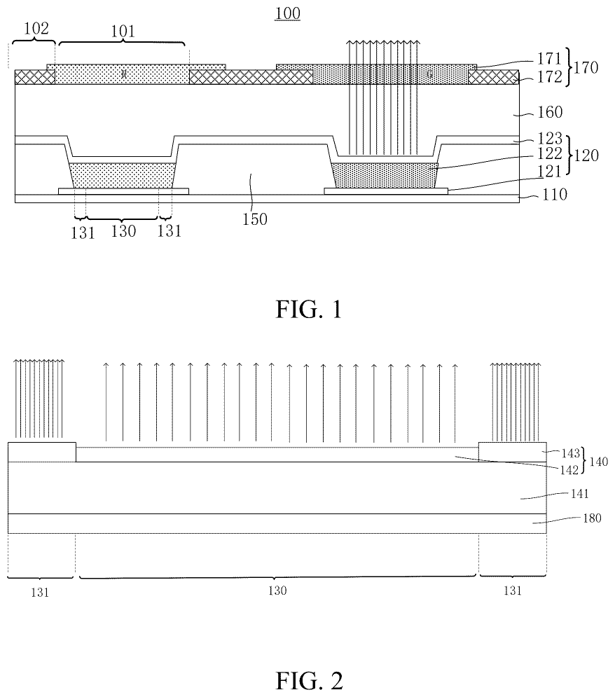

FIG. 1 is a schematic diagram of a display panel according to the present application. FIG. 2 is a schematic diagram of a light-emitting element of a first embodiment according to the present application. As shown in FIGS. 1 to 2, the present application discloses a display panel 100. The display panel 100 includes an opening area 101 and a non-opening area 102. The display panel 100 includes a substrate 110, a pixel defining layer 150, and a light-emitting element 120 layer. The pixel defining layer 150 is disposed on the substrate 110 and is located in the non-opening area 102. The light-emitting element 120 layer is disposed on the substrate 110 and is located in the opening area 101. The light-emitting element 120 layer includes a plurality of light-emitting elements 120, and the plurality of light-emitting elements 120 are arranged in an array. Each of the light-emitting elements 120 includes a bottom electrode 121, a light-emitting layer 122, and a top electrode 123. Each light-emitting element 120 includes a middle region 130 and a peripheral region 131. The peripheral region 131 is arranged around the middle region 130. The bottom electrode 121 includes a transparent electrode layer 140 and a reflective electrode layer 141. The transparent electrode layer 140 is arranged on the side of the reflective electrode layer 141 facing away from the substrate 110. The transparent electrode layer 140 includes a first conductive layer 142 and a second conductive layer 143 that are electrically connected. The first conductive layer 142 is arranged corresponding to the middle region 130, and the second conductive layer 143 is arranged corresponding to the peripheral region 131. The thickness of the first conductive layer 142 is less than the thickness of the second conductive layer 143. At the same light-emitting element 120, the brightness of the peripheral region 131 is higher than that of the middle region 130.

In this application, the light-emitting area of each light-emitting element 120 is divided into a middle region 130 and a peripheral region 131, and the thickness of the transparent electrode layer in the bottom electrode of the peripheral region is increased to increase the brightness of the peripheral region 131. As such, the light output of the peripheral region of the light-emitting element 120 is enhanced, and the number of light output rays of the peripheral region is increased. When displaying, the light emitted by the light-emitting element is made more uniform, thereby improving the display effect of the display panel. Furthermore, the edge of the light-emitting element 120 has serious light attenuation, especially when the display panel 100 is viewed at a certain angle, which causes the problem of color deviation at a large viewing angle. The present application increases the thickness of the transparent electrode layer of the peripheral region 131, so that the chromaticity value (Commission Internationale de l'Eclairage, CIE for short) of the peripheral region of the light-emitting element 120 is better than the chromaticity value of the middle region. For example, the CIEy of the peripheral region of the blue light-emitting element may be 0.045˜0.048, and the CIEy of the middle region may be 0.048˜0.052, which improves the color shift phenomenon under a large viewing angle and improves the display effect.

It is worth mentioning that a transparent electrode layer 140 is further disposed on the side of the reflective electrode layer 141 facing towards the substrate 110 to form a three-layer structure of the transparent electrode layer 140, the reflective electrode layer 141, and another transparent electrode layer 140. The main factors affecting the light output efficiency are the reflective electrode layer 141 and the upper transparent electrode layers 140. This application mainly improves the above, and the transparent electrode layer 140 mentioned below refers to the transparent electrode layer 140 disposed on the side of the reflective electrode layer 141 facing away from the substrate 110, and will not be described in detail later. It is understood that the bottom electrode 121 mentioned in the present application mainly refers to the bottom electrode 121 in the effective light-emitting area of the light-emitting element 120, and the connection line of the bottom electrodes 121 or the invalid area of ineffective light emission is not within the scope of discussion of the present application. However, for the non-luminous bottom electrode 121, an even lower refractive index may be set to reduce the problem of ambient light reflection.

Specifically, there may be many ways to brighten the intensity of the light emitted from the peripheral region of the light-emitting element 120, including but not limited to enhancing the light output efficiency of the light-emitting layer 122 of the peripheral region, enhancing the reflectivity of the bottom electrode 121 of the peripheral region, etc. However, relatively speaking, the material of the light-emitting layer 122 has been selected to have a relatively high light extraction efficiency compared to the current technology. On this basis, in an exemplary technical solution, the light extraction efficiency of the light-emitting layer 122 in the middle region 130 can be set lower than the light extraction efficiency of the light-emitting layer 122 in the peripheral region to balance the brightness between the middle region and the peripheral region of the light-emitting element. However, relatively speaking, reducing the brightness of the middle region may lead to a decrease in the overall brightness.

In this regard, in this embodiment, by changing the thickness of the bottom electrode 121, the light extraction efficiency of the middle region 130 is different from that of the peripheral region. The thickness of the bottom electrode 121 corresponding to the middle region 130 is smaller than the thickness of the bottom electrode 121 corresponding to the peripheral region 131. The thinner the bottom electrode 121 is, the lower the corresponding reflectivity is than the thicker bottom electrode 121, so that the light extraction efficiency of the middle region 130 is weaker than that of the peripheral region 131, thereby improving the display effect of the peripheral region. It is worth mentioning that even if the light output efficiency of the middle region 130 is reduced in this application, the purpose itself is not to make the front viewing effect worse, but to sacrifice a little brightness of the front side and make up for the brightness difference between a large viewing angle and a front viewing angle. Furthermore, even if the thickness of the middle region 130 is reduced to a certain extent, it has almost no effect on the front viewing, but it greatly improves the viewing experience at a large viewing angle.

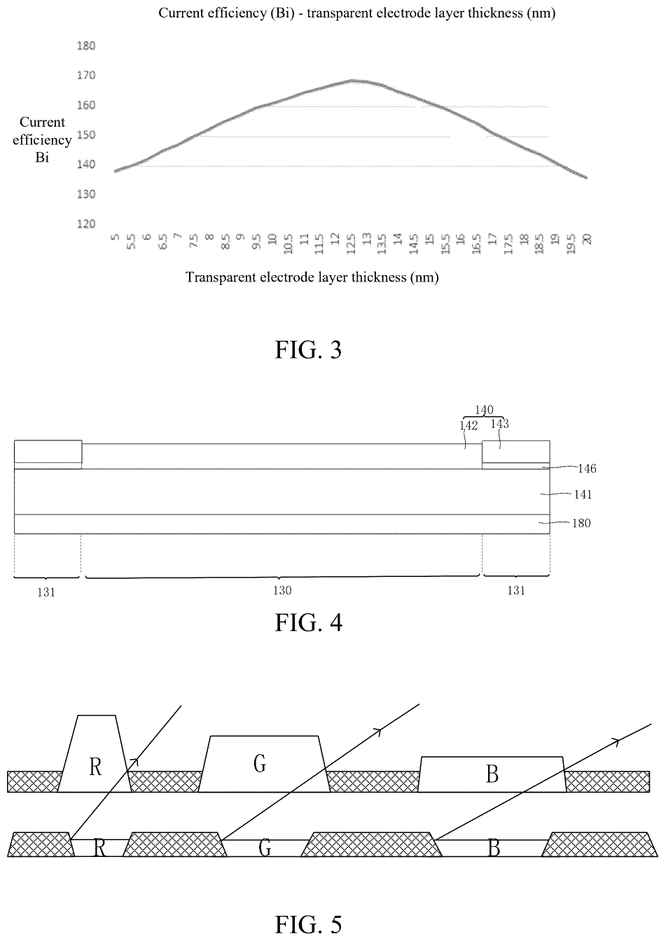

FIG. 3 is a schematic diagram illustrating a relationship between a thickness change of the transparent electrode layer and a current efficiency of the light-emitting element according to this application. As shown in FIG. 3, this experiment tests the current efficiency of the light-emitting element 120 by controlling other variables consistent and only changing the thickness of the upper transparent electrode layer 140 of the bottom electrode 121 of the light-emitting element 120. The horizontal axis denotes the thickness of the transparent electrode layer 140, and the vertical axis denotes the current efficiency of the light-emitting element 120. When the thickness of the transparent electrode layer 140 lies in the range of 5 nm to 12.5 nm, as the thickness of the transparent electrode layer 140 increases, the current efficiency of the light-emitting element 120 gradually increases. When the thickness of the transparent electrode layer 140 lies in the range of 12.5 nm to 20 nm, as the thickness of the transparent electrode layer 140 increases, the current efficiency of the light-emitting element 120 gradually decreases.

Further, the thickness of the second conductive layer 143 lies in the range of 5 nm to 20 nm, and the thickness of the first conductive layer 142 lies in the range of 4 nm to 12 nm. The thickness of the second conductive layer 143 needs to satisfy the requirement that the current efficiency is higher than the current efficiency of the first conductive layer 142. That is, when the thickness of the second conductive layer 143 is selected to be 5 nm to 12.5 nm, the thickness of the second conductive layer 143 needs to be greater than the thickness of the first conductive layer 142. When the thickness of the second conductive layer 143 is selected to be 12.5 nm to 20 nm, it is also required to ensure that the current efficiency of the second conductive layer 143 be higher than the current efficiency of the first conductive layer 142. Relatively speaking, when the thickness of the transparent electrode layer is in the range of 5 nm to 12.5 nm, the thicker the thickness of the second conductive layer 143 is, the better, while when the thickness of the transparent electrode layer is in the range of 12.5 nm to 20 nm, the thinner the thickness of the second conductive layer is, the better, as the slower the brightness decay of the light-emitting element 120 is.

Specifically, the thickness of the second conductive layer 143 may be between 11 nm and 13 nm, while the thickness of the first conductive layer 142 may be between 10 nm and 12 nm. Furthermore, the thickness of the second conductive layer is greater than the thickness of the first conductive layer 142, so that the current efficiency of the second conductive layer 143 is the highest, and the current efficiency of the second conductive layer 143 is higher than the current efficiency of the first conductive layer 142.

Corresponding to the transparent electrode layer 140 in the above embodiment, the specific manufacturing process may include: forming a first transparent electrode layer 140 in the opening area 101, removing the transparent electrode layer 140 in the middle region 130, and then forming a second transparent electrode layer 140 again, so as to form different thicknesses, and the thickness of the second conductive layer 143 in the peripheral region is greater than the thickness of the first conductive layer 142 in the middle region 130.

In another embodiment, the refractive index of the second conductive layer 143 is greater than the refractive index of the first conductive layer 142. In this embodiment, the first conductive layer 142 and the second conductive layer 143 may be formed using different materials so that the refractive index of the second conductive layer 143 is higher than the refractive index of the first conductive layer 142. In addition to being related to the thickness of the above-mentioned ITO material, the light-emitting intensity of the light-emitting element 120 is also related to the refractive index of ITO, and the higher the refractive index of the ITO material, the higher the light-emitting intensity of the corresponding light-emitting element 120. In this embodiment, materials with different refractive indices are selected to form transparent electrode layers 140 with different refractive indices, which are respectively used as the first conductive layer 142 and the second conductive layer 143. As such, the refractive index of the second conductive layer 143 is higher than that of the first conductive layer 142, and the difference between the refractive index of the first conductive layer 142 and the refractive index of the second conductive layer 143 lies in the range of 0.1 to 0.5. Specifically, the ITO material and the organic layer material have similar refractive indexes, and the thickness change of ITO can change the brightness of the light-emitting element 120. Specifically, the refractive index of the second conductive layer lies between 2 and 2.3, and the refractive index of the first conductive layer lies between 1.6 and 1.8.

Corresponding to the transparent electrode layer 140 in this embodiment, the specific manufacturing process may include: forming the first transparent electrode layer 140 in the opening area 101 using the first transparent electrode material, patterning the first transparent electrode layer 140 to form the first conductive layer 142, and forming a photoresist layer on the first conductive layer 142. Then a second transparent electrode layer 140 is formed in the opening area 101 using a second transparent electrode material, and then the second transparent electrode layer 140 on the first conductive layer 142 is removed, a first conductive layer 142 is formed in the middle region 130, and a second conductive layer 143 is formed in the peripheral region 131. It is worth mentioning that the connection line of the bottom electrodes 121 in the non-opening area 102 may also be formed by a transparent electrode material with a low refractive index to reduce ambient light reflection.

In another embodiment, the work function of the second conductive layer 143 is set to be between 4.9 eV and 5.1 eV, and the work function of the first conductive layer 142 is set to be between 4.6 eV and 4.8 eV. In this embodiment, the work function of the second conductive layer 143 is made higher than the work function of the first conductive layer 142, and the difference between the two may lie in the range between 0.1 eV and 0.5 eV. In this embodiment, the conductive ability of the second conductive layer is mainly enhanced so that the hole injection ability of the second conductive layer of the peripheral region is stronger than that of the second conductive layer of the middle region, and the light output brightness of the peripheral region corresponding to the second conductive layer 143 is also enhanced and the attenuation is weakened, so as to achieve the effect of improving the brightness of the peripheral region.

Specific methods to make the work function of the second conductive layer 143 higher than the work function of the first conductive layer 142 include but are not limited to the following methods.

For example, the first conductive layer 142 and the second conductive layer 143 may be formed of different materials. The second conductive layer 143 may be formed of an indium tin oxide (ITO) material, and the first conductive layer 142 may be formed of an indium zinc oxide material. By using different materials, the work function of the second conductive layer 143 is made higher than the work function of the first conductive layer 142.

Of course, in the case where the materials of the first conductive layer 142 and the second conductive layer 143 are identical, the proportions of indium, tin, and oxygen in the materials of the first conductive layer 142 and the second conductive layer 143 may be set accordingly so that the work function of the first conductive layer 142 is lower than the work function of the second conductive layer 143.

It is understandable that the scheme of using different materials for the first conductive layer 142 and the second conductive layer 143 in this embodiment may be used in combination with the scheme of different thicknesses of the first conductive layer 142 and the second conductive layer 143 in the first embodiment, and the thicknesses, materials, etc. of the first conductive layer 142 and the second conductive layer 143 may be selected depending on actual conditions. It is understandable that to achieve the changes of work function and refractive index, different energies, gas pressures, oxygen content ratios, etc. may be used when preparing the first conductive layer 142 of the middle region 130 and the second conductive layer 143 of the peripheral region 131, respectively, and the specific range may be adjusted depending on the actual process.

Specifically, the area of the peripheral region 131 accounts for about 1% to 10% of the total effective light-emitting area, and the total effective light-emitting area is equal to the sum of the areas of the peripheral region 131 and the middle region 130.

FIG. 4 is a schematic diagram of a light-emitting element of a second embodiment of the present application. As shown in FIG. 4, in this embodiment, an isolation layer 146 is further disposed between the transparent electrode layer 140 and the reflective electrode layer 141. Specifically, the bottom electrode 121 further includes an isolation layer 146, and the isolation layer 146 is arranged in the peripheral region 131. The isolation layer 146 is arranged between the transparent electrode layer 140 and the reflective electrode layer 141.

In this embodiment, an isolation layer 146 is disposed on the peripheral region of the reflective electrode layer 141, and the material of the isolation layer 146 may be one or more materials of silicon oxide, silicon nitride, or silicon oxynitride. That is, a layer of silicon oxide, silicon nitride, or silicon oxynitride is deposited on the reflective electrode layer 141. The exposure, development, and etching method can be used to deposit a layer of silicon oxide, silicon nitride, or silicon oxynitride in the specified area of the peripheral region 131. Since silicon oxide, silicon nitride, or silicon oxynitride are different types of materials compared with the reflective electrode layer 141, there will be no etching effect on the reflective electrode layer in the bottom electrode. Finally, a transparent electrode layer is deposited. The thickness of the reflective electrode layer 141 needs to be greater than or equal to 80 nm, where the specific value may be 100 nm. The thickness of silicon oxide, silicon nitride, or silicon oxynitride ranges from 1 nm to 20 nm, which can improve the edge CIE value and make the CIE of the peripheral region and the CIE of the middle region closer. While improving the CIE of the peripheral region, the light-emitting brightness of the peripheral region is improved, so that the brightness of the peripheral region is close to that of the middle region. Specifically, a second conductive layer 143 may be disposed on the isolation layer 146.

In one embodiment, the display panel 100 of the present application is an OLED display panel 100 with a polarizer-free technology, which is called POL-less technology, or COE (Color On Encapsulation) display panel 100. That is, the polarizer in the OLED display panel 100 is removed, and the color filter layer 170 is configured to filter the light instead. The color filter layer 170 may be formed on the encapsulation layer 160 of the light-emitting element 120 layer, or under the encapsulation layer 160. This application only takes the color filter layer 170 formed on the encapsulation layer 160 as an example for explanation. It can be understood that the design of this application can be applied to a variety of COE display panels 100, such as the solution of disposing the color filter layer 170 under the encapsulation layer 160 also falls in the scope of protection of this application.

Specifically, the display panel 100 further includes an encapsulation layer 160 and a color filter layer 170. The encapsulation layer 160 is configured to encapsulate the light-emitting element layer. The encapsulation layer 160 is arranged on the light-emitting element layer. The color filter layer 170 is arranged on the encapsulation layer 160.

Generally speaking, a driving layer, i.e., a thin film transistor layer, is further disposed between the substrate 110 and the light-emitting elements 120. The driving layer includes a plurality of thin film transistors arranged in an array. The output end, i.e., the drain electrode, of each thin film transistor is connected to the bottom electrode 121 of the respective light-emitting element 120 through a via hole. Through the control of the thin film transistor, different data signals are transmitted to the bottom electrode 121 of each light-emitting element 120 to achieve different luminous displays.

FIG. 5 is a schematic diagram of a color filter layer of the present application. In connection with FIGS. 1 to 5, the color filter layer 170 includes a red filter, a green filter, a blue filter, and a black matrix 172. The black matrix 172 is arranged in the non-opening area 102, and a plurality of openings are defined in the black matrix 172 corresponding to the opening area 101. The plurality of red filters, green filters, and blue filters are arranged in the respective openings. The light-emitting elements 120 include a red light-emitting element 120, a green light-emitting element 120, and a blue light-emitting element 120. The red filter is disposed corresponding to the red light-emitting element 120, the green filter is disposed corresponding to the green light-emitting element 120, and the blue filter is disposed corresponding to the blue light-emitting element 120.

In this embodiment, it is considered that the light transmittances of the red filter, the blue filter, and the green filter are different, and the light-emitting brightnesses of the red light-emitting element 120, the green light-emitting element 120, and the blue light-emitting element 120 are different. In this regard, the present application sets the area of each color filter 171 and the effective light-emitting area of each light-emitting element 120 differently, so that the color saturation of the display panel 100 is higher. For example, the area of the blue filter may be greater than or equal to the area of the green filter, and the area of the green filter may be greater than or equal to the area of the red filter. The area of the blue sub-pixel is set relatively larger, while the area of the red sub-pixel is set relatively smaller, so that the corresponding color saturation of the display panel 100 may be higher.

However, similarly, since the opening areas corresponding to the sub-pixels of different colors are different, the angular ranges of the emitted light rays of the light-emitting elements 120 of different colors are different. At a relatively large viewing angle, there may be the situation where only the emitted light of the blue light-emitting element 120 can be received, and at another larger viewing angle, the emitted light of the red light-emitting element 120 cannot be received, thereby causing the color shift phenomenon at a large viewing angle. It is worth mentioning that when viewing at a large viewing angle, since the outgoing light of the middle region 130 will be blocked by the shielding layer, the main outgoing light at a large viewing angle is provided by the peripheral region. Therefore, the present application focuses on enhancing the outgoing light of the peripheral region to improve the display effect at a large viewing angle.

Correspondingly, the present application enhances the light intensity of the peripheral region of each light-emitting element 120 to increase the number of large-angle emitted light rays from the peripheral regions. Specifically, in this embodiment, at least the red light-emitting element 120 adopts the above design to enhance the outgoing light of the red light-emitting element 120 under a large viewing angle. Of course, in practice, the light-emitting elements 120 of different colors may be designed depending on the color deviation under a large viewing angle, so as to improve the color deviation under a large viewing angle and enhance the quality of the display panel 100. The specific scheme includes but is not limited to making one, two, or three of the red light-emitting element 120, the green light-emitting element 120, and the blue light-emitting element 120 simultaneously be each implemented as a light-emitting element 120 having a stronger outgoing light in the peripheral region.

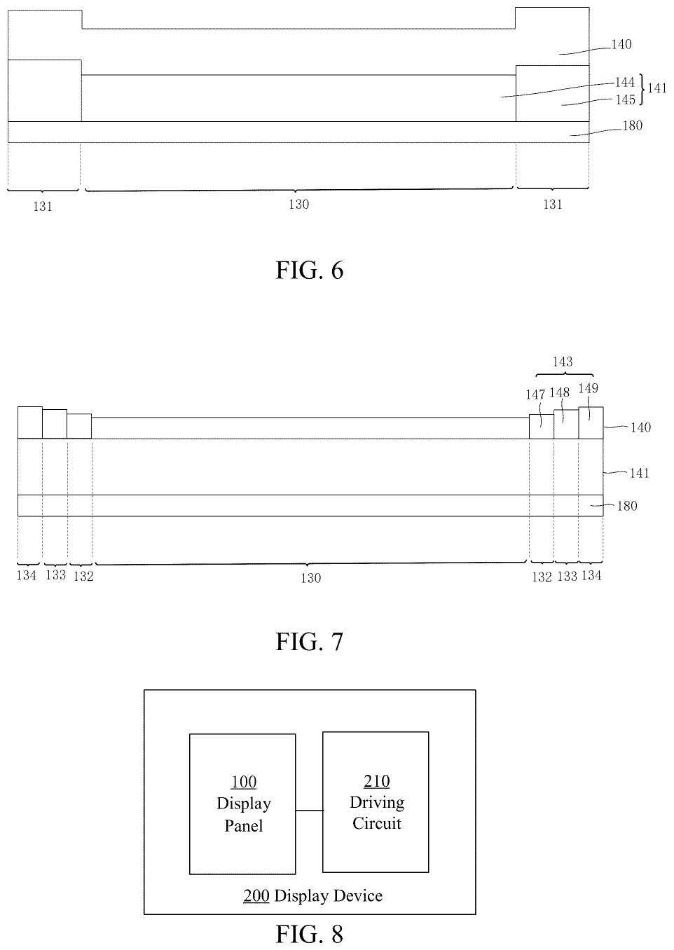

FIG. 6 is a schematic diagram of a light-emitting element of a third embodiment of the present application. As shown in FIG. 6, in this embodiment, the thickness of the reflective electrode layer 141 may be designed to be different, and the reflective electrode layer 141 may be formed of a silver material. Specifically, the reflective electrode layer 141 includes a third electrode layer 144 and a fourth electrode layer 145. The third electrode layer 144 is arranged corresponding to the middle region 130, and the fourth electrode layer 145 is arranged corresponding to the peripheral region. The thickness of the fourth electrode layer 145 is greater than the thickness of the third electrode layer 144.

In this embodiment, the thickness of the upper transparent electrode layer 140 is 10 nm, the thickness of the lower transparent electrode layer 180 is 10 nm, the thickness of the third electrode layer 144 is 100 nm, and the thickness of the fourth electrode layer 145 is greater than 130 nm. Relatively speaking, the thicker the reflective electrode layer 141, the higher the reflectivity, then the corresponding light-emitting element 120 has a higher light-emitting brightness. In this embodiment, the light-emitting brightness of the light-emitting element 120 of the peripheral region can be enhanced by simply changing the thickness of the reflective electrode layer 141. Specifically, the area of the peripheral region accounts for about 1% to 10% of the total effective light-emitting area, and the total effective light-emitting area is equal to the sum of the areas of the peripheral region and the middle region 130.

FIG. 7 is a schematic diagram of a third bottom electrode of the present application. As shown in FIG. 7, the peripheral region 131 includes a first peripheral region 132, a second peripheral region 133, and a third peripheral region 134. The first peripheral region 132 is arranged around the middle region 130. The second peripheral region 133 is arranged around the first peripheral region 132. The third peripheral region 134 is arranged around the second peripheral region 133. The second conductive layer 143 includes a first edge conductive layer 147, a second edge conductive layer 148, and a third edge conductive layer 149. The first edge conductive layer 147 is arranged corresponding to the first peripheral region 132. The second edge conductive layer 148 is arranged corresponding to the second peripheral region 133. The third edge conductive layer 149 is arranged corresponding to the third peripheral region 134. The thicknesses of the first edge conductive layer 147, the second edge conductive layer 148, and the third edge conductive layer 149 gradually increase.

In this embodiment, a transparent electrode layer 140 with a stepped thickness is formed on the bottom electrode 121 of the light-emitting element 120, and the thickness of the thickest transparent electrode layer 140 is about 12.5 nm.

FIG. 8 is a schematic diagram of a display device of the present application. As shown in FIG. 8, the present application further discloses a display device. The display device 200 includes a driving circuit 210 and the display panel 100 in any of the above embodiments, where the driving circuit 210 is used to drive the display panel 100 to display.

In the present application, the light-emitting area of each light-emitting element 120 is divided into a middle region 130 and a peripheral region 131, and on this basis, the brightness of the peripheral region 131 is increased. Generally speaking, the edge of the light-emitting element 120 has serious light attenuation, especially when the display panel 100 is viewed at a certain angle, which causes the problem of color deviation at a large viewing angle. In this application, by increasing the brightness of the peripheral region 131, the light output of the peripheral region of the light-emitting element 120 is enhanced, and the amount of light output of the peripheral region is increased. When displaying, the light output at a large viewing angle is enhanced, the color shift phenomenon of the display at a large viewing angle is improved, and the display effect is improved.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling within the scope of protection of the present application.

What is claimed is:

1. A display panel, comprising an opening area and a non-opening area, wherein the display panel comprises:
a substrate;
a pixel defining layer, arranged on the substrate and disposed in the non-opening area; and
a light-emitting element layer, arranged on the substrate and disposed in the opening area, the light-emitting element layer comprising a plurality of light-emitting elements that are arranged in an array;
wherein each of the plurality of light-emitting elements comprises a bottom electrode, a light-emitting layer, and a top electrode; wherein each of the plurality of light-emitting elements comprises a middle region and a peripheral region, the peripheral region being disposed around the middle region;
wherein the bottom electrode comprises a transparent electrode layer and a reflective electrode layer, wherein the transparent electrode layer is arranged on a side of the reflective electrode layer facing away from the substrate, wherein the transparent electrode layer comprises a first conductive layer and a second conductive layer electrically connected to each other, wherein the first conductive layer is arranged corresponding to the middle region, wherein the second conductive layer is arranged corresponding to the peripheral region, wherein the first conductive layer has a thickness less than a thickness of the second conductive layer;
wherein at each same light-emitting element, the peripheral region has a brightness higher than a brightness of the middle region.

2. The display panel as recited in claim 1, wherein the second conductive layer has a refractive index greater than a refractive index of the first conductive layer.

3. The display panel as recited in claim 2, wherein the second conductive layer has a refractive index that lies in the range of 2 to 2.3, and wherein the first conductive layer has a refractive index that lies in the range of 1.6 to 1.8.

4. The display panel as recited in claim 1, wherein the second conductive layer is formed of an indium tin oxide material, and the first conductive layer is formed of an indium zinc oxide material.

5. The display panel as recited in claim 1, wherein the bottom electrode further comprises an isolation layer arranged in the peripheral region, the isolation layer being arranged between the transparent electrode layer and the reflective electrode layer.

6. The display panel as recited in claim 1, wherein the second conductive layer has a thickness that lies in the range of 5 nm to 20 nm, and wherein the first conductive layer has a thickness that lies in the range of 4 nm to 10 nm; wherein a difference between the thickness of the second conductive layer and the thickness of the first conductive layer lies in the range between 0.5 nm and 10 nm.

7. The display panel as recited in claim 6, wherein the second conductive layer has a thickness that lies in the range of 11 nm to 13 nm; wherein the first conductive layer has a thickness that lies in the range of 10 nm to 12 nm, and wherein the thickness of the second conductive layer is greater than the thickness of the first conductive layer.

8. The display panel as recited in claim 1, wherein the second conductive layer has a work function that lies in the range of 4.9 eV to 5.1 eV; and the first conductive layer has a work function that lies in the range of 4.6 eV to 4.8 eV.

9. The display panel as recited in claim 8, wherein the second conductive layer is formed of an indium tin oxide (ITO) material, and wherein the first conductive layer is formed of an indium zinc oxide material.

10. The display panel as recited in claim 1, wherein the peripheral region has an area that accounts for substantially 1% to 10% of a total effective light-emitting area, the total effective light-emitting area being equal to a sum of areas of the peripheral region and the middle region.

11. The display panel as recited in claim 3, wherein the peripheral region comprises a first peripheral region, a second peripheral region, and a third peripheral region; wherein the first peripheral region is arranged around the middle region, wherein the second peripheral region is arranged around the first peripheral region, and wherein the third peripheral region is arranged around the second peripheral region;
wherein the second conductive layer comprises a first edge conductive layer, a second edge conductive layer, and a third edge conductive layer; wherein the first edge conductive layer is disposed corresponding to the first peripheral region, wherein the second edge conductive layer is disposed corresponding to the peripheral region, wherein the third edge conductive layer is disposed corresponding to the third peripheral region;
wherein the thicknesses of the first edge conductive layer, the second edge conductive layer, and the third edge conductive layer gradually increase.

12. The display panel as recited in claim 5, further comprising an encapsulation layer and a color filter layer, wherein the encapsulation layer is configured to encapsulate the light-emitting layer, wherein the encapsulation layer is arranged on the light-emitting layer; wherein the color filter layer is arranged on the encapsulation layer;
wherein the color filter layer comprises a red filter, a green filter, a blue filter, and a black matrix; wherein the black matrix is arranged in the non-opening area, and wherein the black matrix comprises a plurality of openings corresponding to the opening area; wherein the plurality of red filters, green filters, and blue filters are arranged in the respective plurality of openings in the black matrix; wherein the blue filter has an area that is greater than or equal to an area of the green filter, and wherein the green filter has an area that is greater than or equal to an area of the red filter.

13. The display panel as recited in claim 12, wherein the plurality of light-emitting elements comprise a red light-emitting element, a green light-emitting element, and a blue light-emitting element; wherein the red light-emitting element has a light-emitting area that is less than or equal to a light-emitting area of the green light-emitting element, wherein the green light-emitting element has a light-emitting area that is less than or equal to a light-emitting area of the blue light-emitting element;
wherein the first conductive layer is disposed in at least the red light-emitting element.

14. The display panel as recited in claim 1, wherein the reflective electrode layer comprises a third electrode layer and a fourth electrode layer, wherein the third electrode layer is arranged corresponding to the middle region, wherein the fourth electrode layer is arranged corresponding to the peripheral region; wherein the fourth electrode layer has a thickness that is greater than a thickness of the third electrode layer.

15. A display device, comprising a display panel and a driving circuit configured to drive the display panel to display; wherein the display panel comprises an opening area and a non-opening area, wherein the display panel comprises:
a substrate;
a pixel defining layer, arranged on the substrate and disposed in the non-opening area; and
a light-emitting element layer, arranged on the substrate and disposed in the opening area, the light-emitting element layer comprising a plurality of light-emitting elements that are arranged in an array;
wherein each of the plurality of light-emitting elements comprises a bottom electrode, a light-emitting layer, and a top electrode; wherein each of the plurality of light-emitting elements comprises a middle region and a peripheral region, the peripheral region being disposed around the middle region;
wherein the bottom electrode comprises a transparent electrode layer and a reflective electrode layer, wherein the transparent electrode layer is arranged on a side of the reflective electrode layer facing away from the substrate, wherein the transparent electrode layer comprises a first conductive layer and a second conductive layer electrically connected to each other, wherein the first conductive layer is arranged corresponding to the middle region, wherein the second conductive layer is arranged corresponding to the peripheral region, wherein the first conductive layer has a thickness less than a thickness of the second conductive layer;
wherein at each same light-emitting element, the peripheral region has a brightness higher than a brightness of the middle region.

16. The display device as recited in claim 15, wherein the second conductive layer has a refractive index greater than a refractive index of the first conductive layer.

17. The display device as recited in claim 16, wherein the second conductive layer has a refractive index that lies in the range of 2 to 2.3, and wherein the first conductive layer has a refractive index that lies in the range of 1.6 to 1.8.

18. The display device as recited in claim 15, wherein the second conductive layer is formed of an indium tin oxide material, and wherein the first conductive layer is formed of an indium zinc oxide material.

19. The display device as recited in claim 15, wherein the bottom electrode further comprises an isolation layer arranged in the peripheral region, wherein the isolation layer is arranged between the transparent electrode layer and the reflective electrode layer.

20. The display device as recited in claim 15, wherein the second conductive layer has a thickness that lies in the range of 5 nm to 20 nm, and the first conductive layer has a thickness that lies in the range of 4 nm to 10 nm; wherein a difference between the thickness of the second conductive layer and the thickness of the first conductive layer lies in the range between 0.5 nm and 10 nm.
